(19) United States
(12) Patent Application Publication
(10) Pub. No.: US 2009/0085987 A1
(43) Pub. Date: Apr. 2, 2009

(54) Method for Manufacturing Liquid Ejecting Head, and Liquid Ejecting Head

(75) Inventors: Toshikazu NIKI, Matsumoto-shi (JP); Nobuyuki TAKEHANA, Matsumoto-shi (JP)

Correspondence Address: HOGAN & HARTSON L.L.P., 1999 AVENUE OF THE STARS, SUITE 1400, LOS ANGELES, CA, 90067, US

(73) Assignee: SEIKO EPSON CORPORATION, Tokyo (JP)

(21) Appl. No.: 12/243,647

(22) Filed: Oct. 1, 2008

(30) Foreign Application Priority Data
Oct. 1, 2007 (JP) 2007-257736

(51) Int. Cl. B41J 2/045; H01L 41/22

(52) U.S. Cl. 347/70; 29/25.35

(57) ABSTRACT

There is provided a manufacturing method of a liquid ejecting head including an unit having a plurality of piezoelectric elements and a fixing plate supporting the piezoelectric elements, a case having an accommodation space for accommodating the unit, and a flow path unit having a vibration plate, a reference portion which becomes a reference of an arrangement position of the unit in the accommodation space being provided on at least a surface among inner wall surfaces partitioning the accommodation space. The manufacturing method of the liquid ejecting head including regulating the arrangement position of the unit in the accommodation space by accommodating the unit in the accommodation space and by making contact of the fixing plate with the reference portion by a bias force applied by a bias member, and bonding and fixing the piezoelectric elements and the vibration plate and bonding and fixing the fixing plate and the case in the state where the arrangement position of the unit is regulated.

### BACKGROUND

1. Technical Field

The present invention relates to a method for manufacturing a liquid ejecting head and a liquid ejecting head preferably used for ejecting liquid (function liquid) such as ink, and in particular to a manufacturing method of a liquid ejecting head and a liquid ejecting head equipped with an oscillator unit having a plurality of piezoelectric elements and a fixing plate for supporting the piezoelectric elements, and a case having an accommodation space for accommodating the oscillator unit.

2. Related Art

An oscillator unit in which a piezoelectric element group is bonded to a fixing plate, a case made of a resin in which an accommodation space capable of accommodating the oscillator unit is formed, and a flow path unit bonded to a distal end of the case are equipped in some of conventional ink jet type recording heads (hereinafter, simply referred to as recording head) (for example, JP-A-2003-053970).

A free end of each piezoelectric element is exposed outward the case through a distal side opening of the accommodation space, and a distal surface is bonded to an island portion (diaphragm portion) of a vibration plate. The vibration plate is deformed by the extension and contraction of the free end to change the capacity of a pressure chamber. Further, the fixing plate of the oscillator unit is manufactured by stainless steel and is bonded to an inner wall surface of the accommodation space of the case by adhesion.

Incidentally, the recording head having the structure is designed so that a clearance is formed between an inner-wall surface partitioning the accommodation space and the oscillator unit. With the clearance, the oscillator unit can be smoothly inserted into the accommodation space of the case. It is necessary that the size of the clearance is, for example, about ten-add μm in order to assure working property of assembling.

However, after the recording head assembled, there is a problem in that it is difficult to assure accuracy of positioning the oscillator unit in the accommodation space due to the presence of the clearance. Then if the free end of the piezoelectric element is displaced with respect to the island portion, there is a fear that ejection property of ink is adversely affected.

### SUMMARY

An advantage of some aspects of the invention is to provided a manufacturing method for a liquid ejecting head and a liquid ejecting head by which an oscillator unit can be accommodated in an accommodation space of a case with high positional accuracy.

According to a first aspect of the invention, there is provided a manufacturing method of a liquid ejecting head including an oscillator unit having a plurality of piezoelectric elements and a fixing plate supporting the piezoelectric elements, a case having an accommodation space for accommodating the oscillator unit, and a flow path unit having a vibration plate, a reference portion which becomes a reference of an arrangement position of the oscillator unit in the accommodation space being provided on at least a surface among inner wall surfaces partitioning the accommodation space. The manufacturing method of the liquid ejecting head including regulating the arrangement position of the oscillator unit in the accommodation space by accommodating the oscillator unit in the accommodation space and by making contact of the fixing plate with the reference portion by a bias force applied by a bias member, and bonding and fixing the piezoelectric elements and the vibration plate and bonding and fixing the fixing plate and the case in the state where the arrangement position of the oscillator unit is regulated.

According to the first aspect of the invention, the arrangement position of the oscillator unit in the accommodation space is regulated by accommodating the oscillator unit in the accommodation space and by making contact of the fixing plate with the reference portion by a bias force applied by the bias member. Accordingly, the oscillator unit can be accommodated in and fixed to the accommodation space with a high positioning accuracy while assuring a clearance which is necessary for assembling operation. Herewith, displacement of the distal portion of the piezoelectric element with respect to a diaphragm portion can be prevented. As a result, productivity can be improved.

According to a second aspect of the invention, there is provided a liquid ejecting head including an oscillator unit having a plurality of piezoelectric elements and a fixing plate supporting the piezoelectric elements, a case having an accommodation space for accommodating the oscillator unit, and a flow path unit having a vibration plate. The liquid ejecting head including a reference portion which becomes a reference of an arrangement position of the oscillator unit in the accommodation space, the reference portion being provided at least on a surface among inner wall surfaces partitioning the accommodation space, and a bias member for biasing the fixing plate of the oscillator unit accommodated in the accommodation space to the reference portions side. The arrangement position of the oscillator unit in the accommodation space is regulated by accommodating the oscillator unit in the accommodation space and by making contact of the fixing plate with the reference portion by a bias force applied by the bias member, and the piezoelectric elements and the vibration plate are bonded and fixed and the fixing plate and the case are bonded and fixed in the state where the arrangement position of the oscillator unit is regulated.

According to the second aspect of the invention, a reference portion which becomes a reference of an arrangement position of the oscillator unit in the accommodation space is provided at least on a surface among inner wall surfaces partitioning the accommodation space, and a bias member for biasing the fixing plate of the oscillator unit accommodated in the accommodation space to the reference portions side is provided. Then, the arrangement position of the oscillator unit in the accommodation space is regulated by accommodating the oscillator unit in the accommodation space and by making contact of the fixing plate with the reference portion by a bias force applied by the bias member. Accordingly, the oscillator unit can be accommodated in and fixed to the accommodation space with a high positioning accuracy. Herewith, displacement of the distal portion of the piezoelectric element with respect to a diaphragm portion can be prevented. As a result, deterioration of ejecting property of liquid caused by displacement of the piezoelectric element can be restrained.

It is preferable that the reference potion is constituted by contact protrusions protruding from the inner wall surface of the accommodation space, a distal surface of each contact protrusion uniformed in a same surface is used as a reference surface which becomes a reference of the arrangement position of the oscillator unit, and the fixing plate of the oscillator unit is made contact with the reference surface by a bias force applied by the bias member in the liquid ejecting head according to the second aspect of the invention.

With the structure, the reference potion is constituted by contact protrusions protruding from the inner wall surface of the accommodation space, and a distal surface of each contact protrusion uniformed in a same surface is used as a reference surface which becomes a reference of the arrangement position of the oscillator unit. Accordingly, the arrangement position of the oscillator unit can be regulated in the state which is closer to a point contact state than the case where an entire surface among the inner walls of the accommodation space is used as the reference surface. Herewith, the positioning accuracy can be further enhanced.

It is preferable that the bias member is constituted by a plate gage in the liquid ejecting head according to the second aspect of the invention.

It is also preferable that the bias member is constituted by a plate spring in the liquid ejecting head according to the second aspect of the invention.

It is also preferable that the bias member is constituted by a rib provided on one of the wall surfaces of the accommodation space, the wall surface opposing the wall surface on which the contact protrusions are provided, in the liquid ejecting head according to the second aspect of the invention.

With the structure, the rib as the bias member can be integrally formed with the case, so that it is not necessary to separately prepare bias member. Further, labor for accommodating bias member in the accommodation space can be omitted.

### BRIEF DESCRIPTION OF THE DRAWINGS

The invention will be described with reference to the accompanying drawings, wherein like numbers reference like elements.

FIG. 1 is a perspective view showing a recording head.

FIG. 2 is an exploded perspective view showing the recording head.

FIG. 3 is a main part cross sectional view showing the recording head.

FIG. 4 is a perspective view showing an oscillator unit.

FIG. 5 is an enlarged perspective view showing a connection portion between piezoelectric elements and island portions.

FIG. 6 is a cross sectional view showing a case.

FIG. 7 is a top view showing the case.

FIG. 8 is a cross sectional view taken along the line VIII-VIII of FIG. 7.

FIG. 9 is a cross sectional view taken along the line IX-IX of FIG. 7.

FIG. 10 is a cross sectional view showing a case for illustrating a structure of a second embodiment.

FIG. 11 is a cross sectional view showing a case for illustrating a structure of a third embodiment.

FIG. 12 is a cross sectional view showing the case for illustrating a structure of a fourth embodiment.

### DESCRIPTION OF EXEMPLARY EMBODIMENTS

Hereinafter, the best mode for carrying out the invention will be described with reference to the accompanying drawings. Various limitations are imposed as a preferable concrete example of the invention in an embodiment described below. However, the scope of the invention is not limited to the embodiment unless such a description for restricting the invention is made in the following description. Further, the following description is made by exemplifying an ink jet type recording head (recording head) as a liquid ejecting head of the invention.

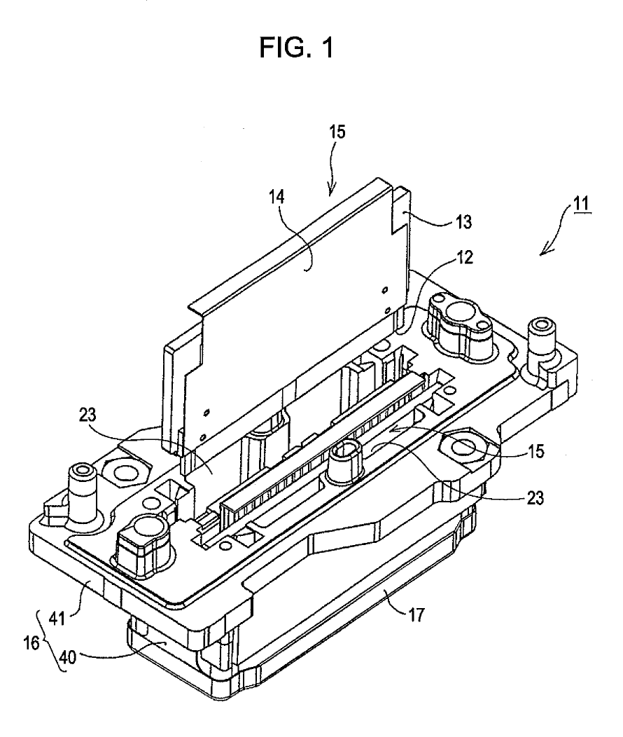

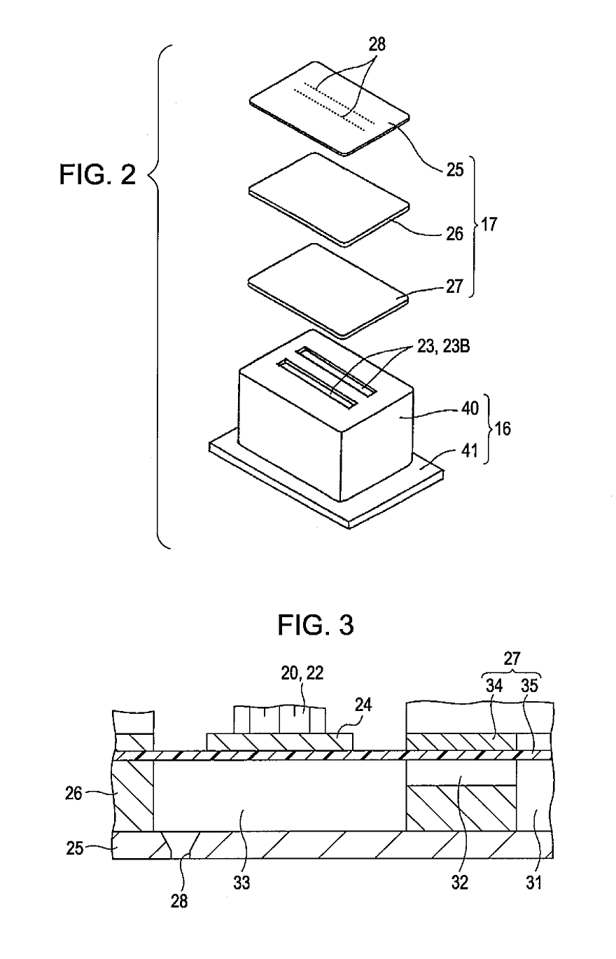

FIG. 1 is a perspective view showing a recording head 11, and FIG. 2 is an exploded perspective view showing the recording head 11.

The exemplified recording head 11 is equipped with a oscillator unit 15 in which a piezoelectric oscillation group 12 in which a plurality of piezoelectric elements 20 are arranged and a fixing plate 13 are unitized, a case 16 capable of accommodating the oscillator unit 15, and a flow path unit 17 bonded to a distal surface of the case 16.

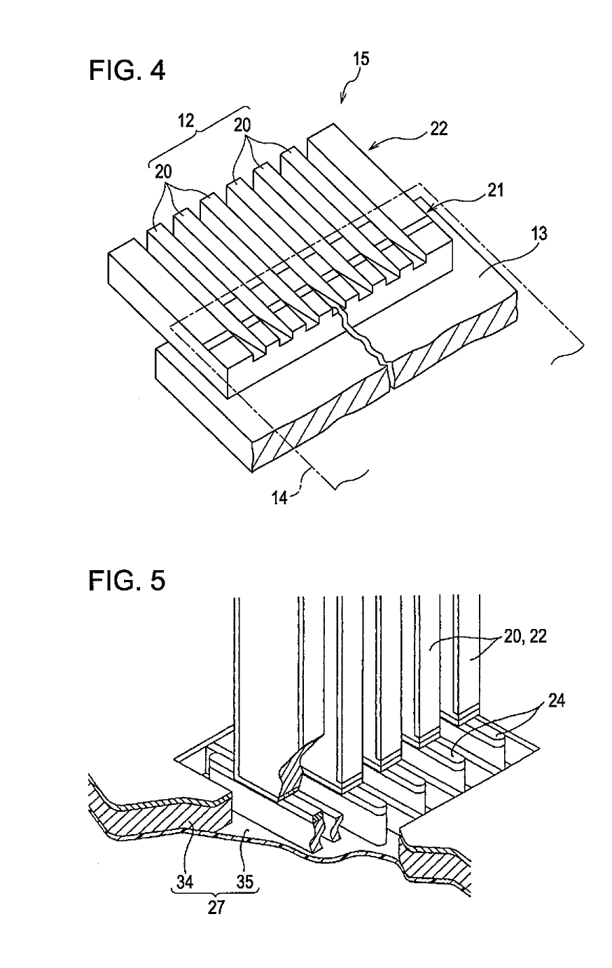

First, the oscillator unit 15 will be described. As shown in FIG. 4, the piezoelectric elements 20 constituting the piezoelectric element group 12 are formed like an elongated comb tooth in a vertical direction, and are separately cut to have a very small width of approximately 50 to 100 μm, for example. Then, the piezoelectric element 20 is constituted as a piezoelectric element of a vertically oscillation type that can be elongated and contracted in a vertical direction (element longitudinal direction). A fixed end 21 of each piezoelectric element 20 is united on the fixing substrate 13. Herewith, a free end 22 is protruded outward from the distal end of the fixing plate 13. More specifically, the piezoelectric elements 20 are supported on the fixing plate 13 in a so called cantilevered manner. Moreover, the length of the fixed end 21 is determined so as to be shorter than the length of the fixing plate 13. The fixed end 21 is bonded to a front side portion (distal side portion) of the fixing plate 13. Note that a distal end of the free end 22 of each piezoelectric element 20 is bonded to a corresponding island portion 24 (diaphragm portion) of the flow path unit 17 (see FIG. 3 and FIG. 5).

A flexible cable 14 for applying a driving signal to the piezoelectric element 20 of the oscillator unit 15 is electrically connected to the piezoelectric element 20 at the side surface of the fixed end 21 opposite to the fixing plate 13 side. Further, the fixing plate 13 supporting each piezoelectric element 20 is constituted by a plate-like member having rigidity capable of receiving reaction force from the piezoelectric element 20. In the embodiment, the fixing plate 13 is manufactured by a stainless steel plate whose thickness is about 1 mm.

Next, the flow path unit 17 will be described. As shown in FIGS. 2, 3 the flow path unit 17 is constituted by a nozzle plate 25, a flow path forming substrate 26, and a vibration plate 27. The flow path unit 17 is constituted by disposing and laminating the nozzle plate 25 on one surface of the flow path forming substrate 26 and disposing and laminating the vibrating plate 27 on the other surface of the flow path forming substrate 26 that is opposite to the side of the nozzle plate 25, and integrating them through adhesion or the like.

The nozzle plate 25 is a thin plate made of stainless steel which has a plurality of nozzle openings 28 provided in a row at a pitch corresponding to a dot formation density. In the embodiment, for example, 180 nozzle openings 28 are provided in a row to constitute a nozzle row with the nozzle openings 28, and two nozzle rows are arranged sideways.

The flow path forming substrate 26 is a plate like member in which an ink flow path formed by a common ink chamber 31, ink supply openings 32, and pressure chambers 33 are formed. Specifically, the flow path forming substrate 26 is a plate like member in which a plurality of spaces which become the pressure chambers 33 that are partitioned by partition walls are formed to correspond to each nozzle opening 28, and in which spaces which becomes the ink supply openings 32 and the common ink chamber 31 are formed. Then, the flow path forming substrate 26 of the embodiment is manufactured by etching a silicon wafer.

The pressure chamber 33 is formed as an elongated chamber in the direction perpendicular to the direction in which the nozzle openings 28 are arranged (nozzle row direction). The ink supply opening 32 is formed as a narrowed portion having a narrow flow path width that communicates the pressure chamber 33 and the common ink chamber 31. Further, the common ink chamber 31 is a chamber for supplying the ink stored in an ink cartridge (not shown) to each pressure chamber 33, and is communicated with each pressure chamber 33 via the corresponding ink supply opening 32.

The vibration plate 27 is a composite plate material having a double structure obtained by laminating a resin film 35 such as PPS (polyphenylene sulfide) on a support plate 34 made of a metal such as stainless steel. The vibration plate 27 serves as a diaphragm portion for sealing an opening surface of the pressure chamber 33 and also serves as a compliance unit for sealing an opening surface of the common ink chamber 31. Then, as shown in FIG. 5, a portion of the support plate 34 serving as the diaphragm, that is, a portion of the support plate 34 corresponding to the pressure chamber 33 is etched and removed so that the removed portion becomes a circular shape to form the island portion 24 for bonding the distal end of the free end 22 of the piezoelectric element 20. The island portion 24 has an elongated block shape in the direction perpendicular to the direction in which the nozzle openings 28 are arranged similarly to the planer shape of the pressure chamber 33, and the resin film 35 around the island portion 24 serves as an elastic film. Further, the portion that serves as the compliance portion, that is, the portion of the support plate 34 corresponding to the common ink chamber 31 is removed by the etching to leave only the resin film 35.

Next, the case 16 will be described.

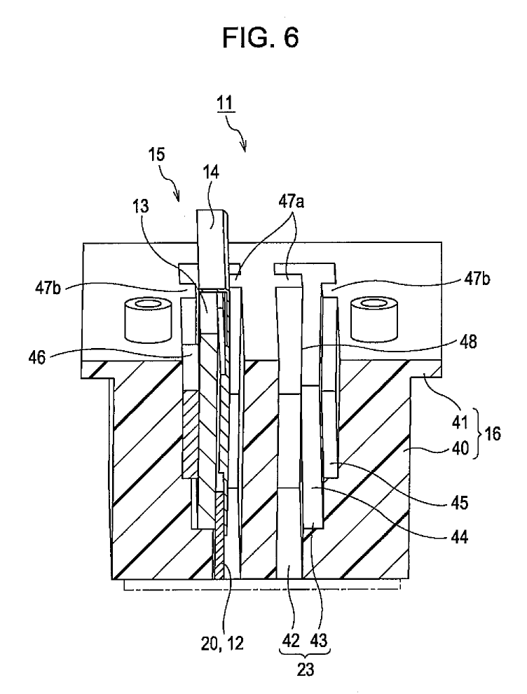

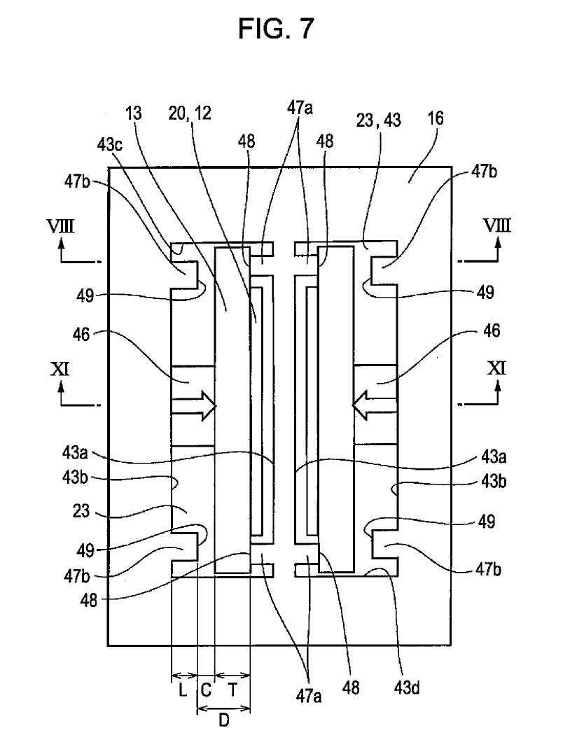

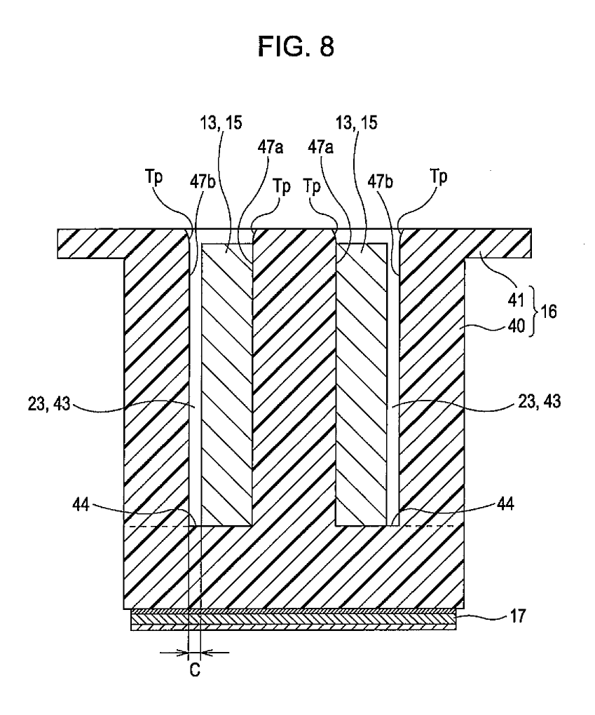

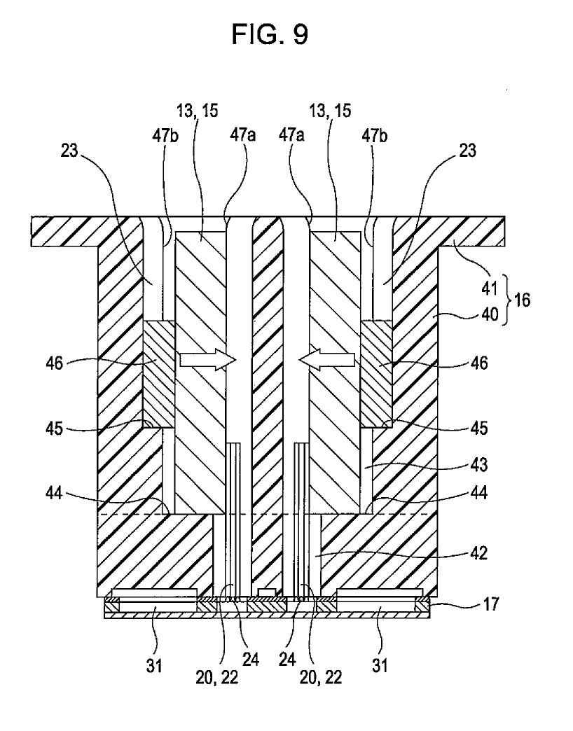

FIG. 6 is a cross sectional view showing the case 16, FIG. 7 is a top view showing the case 16, FIG. 8 is a cross sectional view taken along the line VIII-VIII of FIG. 7, and FIG. 9 is a cross sectional view taken along the line IX-IX of FIG. 7.

The case 16 is a resin member schematically constituted by a case main body 40 having a block shape, a flange unit 41 extended from a proximal portion of the case main body 40 to a side direction. As for the resin constituting the case 16, a thermosetting resin is preferably used because a molding property is excellent, high dimensional precision can be obtained, and necessary rigidity can also be acquired.

An accommodation space 23 capable of accommodating the oscillator unit 15 is formed in the case main body 40. The accommodation space 23 is continuously formed from the distal surface of the case main body 40 that becomes the flow path unit 17 side (that is, the lower surface of the case 16) to the proximal surface (top surface) of the case main body 40 opposite to the distal surface. That is, the accommodation space 23 is formed as a through opening that passes through the case 16 in the height direction from the distal side opening to the proximal side opening. The accommodation space 23 is provided for every oscillator unit 15. For example, the recording head 11 of the embodiment has two nozzle rows, and one oscillator unit 15 is provided for each nozzle row. Accordingly, two accommodation spaces 23 are arranged sideways.

The accommodation space 23 is a continuous space formed by a first accommodation space 42 in which only the piezoelectric element group 12 is inserted and a second accommodation unit 43 in which the piezoelectric element group 12, the fixing plate 13, and the flexible cable 14 are inserted. The first accommodation space 23 has a rectangular opening which is long in the piezoelectric element arrangement direction. The first accommodation unit 42 is formed from the distal surface of the case 16 to the second accommodation unit 43 which is positioned at the proximal surface side than the distal surface to a certain degree. Then, the length of the opening of the first accommodation unit 42 (length in the long side direction) is set slightly longer than the length of the piezoelectric element group 12 in the oscillator arrangement direction. The width of the opening of the first accommodation unit 42 (length in the short side direction) is set to about two times of the thickness of the piezoelectric element 20.

The second accommodation space 43 is continuously formed from the position which is slightly closer to the proximal surface side from the distal surface of the case 16 to the proximal surface so as to be communicated with the first accommodation space 42. That is, the bottom surface of the second accommodation space 43 is provided at a position that is closer to the side of the proximal surface from the distal surface of the case 16 by an approximately free length of the piezoelectric element 20 (length of the free end 22). Then, the length of the opening of the second accommodation space 43 is set slightly longer than the width of the fixing plate 13 (size in the oscillator arrangement direction) and slightly longer than the opening length of the first accommodation space 42. Further, the width of the opening of the second accommodation unit 43 (size in the direction perpendicular to the direction in which piezoelectric elements are arranged or in the direction of the thickness of the fixing plate) is set fully larger than the thickness of the fixing plate 13, and for example, set to about two to three times of the thickness of the fixing plate 13.

A first seat shoulder 44 for regulating the position of the oscillator unit 15 in the accommodation space 23 in the vertical direction is provided at the bottom of the second accommodation unit 43, that is, the border with the first accommodation space 42. More specifically, when the oscillator unit 15 is accommodated in the accommodation space 23, the distal surface of the fixing plate 13 is made contact with the first seat shoulder 44 to regulate the position of the oscillator unit 15 in the vertical direction. Further, a second seat shoulder 45 for seating a plate gage 46 to be described below is formed at a position closer to the proximal surface of the case 16 than the first seat shoulder 44 and at a portion which becomes a back surface side of the fixing plate 13. That is, the bottom of the second accommodation unit 43 is formed to have two steps.

In the first accommodation space 42, on an inner wall surface which becomes the side at which the piezoelectric element group 12 of the piezoelectric unit 15 is accommodated (hereinafter, referred to as first inner wall surface 43a), a first contact protrusion 47a (corresponding to the contact protrusion (reference portion) of the invention) having a vertically long rib shape protruded towered the surface opposing the first inner wall surface 43a (hereinafter, referred to as second inner wall surface 43b) is provided. The first contact protrusion 47a is formed from the bottom of the second accommodation space 43 to the proximal surface of the case 16 along the height direction of the case 16. In the embodiment, as shown in FIG. 7, two first contact protrusions 47a in total are provided one by one at the positions slightly displaced to the center from the both ends of the first inner wall surface 43a. The positions of the first contact protrusions 47a correspond to the both side portions of the piezoelectric element group 12 on the surface of the fixing plate on which the piezoelectric element group is bonded. Further, the distal surfaces of the first contact protrusions 47a (fixing plate contact surfaces) are used as reference surfaces 48 which become a reference of the arrangement position of the oscillator unit 15 (arrangement position in the thickness direction of the fixing plate) in the accommodation space 23, and the reference surfaces 48 are uniformed on a same surface. Further, as shown in FIG. 8, a taper Tp is provided at the upper end potion of the first contact protrusion 47a. Accordingly, the oscillator unit 15 can be smoothly guided at the side of the accommodation space 23.

Note that, in the embodiment, the arrangement position of the oscillator unit 15 in the oscillator arrangement direction is regulated by an inner wall surface (hereinafter, referred to as third inner wall surface 43c) that opposes one side surface of the fixing plate 13 and a fourth inner wall surface 43d opposing the third inner wall surface 43c among the inner wall surfaces of the accommodation space 23.

On the other hand, a second contact protrusion 47b protruded toward the side of the first inner wall surface 43a is provided at a position of the second inner wall surface 43b opposing the first contact protrusion 47a. The second contact protrusion 47b is a member having a vertically long rib shape formed from the bottom of the second accommodation space 43 to the proximal surface of the case 16 along the height direction of the case similarly to the first contact protrusion 47a. Two second contact protrusions 47b are provided in total to correspond to the first contact protrusions 47a. The second contact protrusion 47b serves as a guide rib for roughly guiding the oscillator unit 15 to an arrangement position in the accommodation space 23. Distal surfaces 49 of the second contact protrusions 47b are uniformed on a same surface, and serve as a guide face on which the back surface of the fixing substrate 13 can be slid.

Herein, as shown in FIG. 7, in the recording head 1 having the aforementioned structure, the distance D between the reference surface of the first contact protrusion 47a and the distal surface 49 of the second protrusion 47b is set larger than the thickness T of the fixing plate 13 so that a clearance C is formed between the contact protrusion 47a or 47b and the fixing plate 13. Herewith, the oscillator unit 15 can be smoothly inserted when the oscillator unit 15 is accommodated in the accommodation space 23. It is necessary that the clearance C is, for example, about ten-add μm in order to assure insertion operability of the oscillator unit 15. Accordingly, unless any measure is taken, the oscillator unit 15 is moved in the thickness direction of the fixing plate 13 within the range of the clearance C and an error of the arrangement position may be generated in the accommodation space 23.

Consequently, in the recording head 1 according to the invention, the aforementioned problem is solved by using bias means for biasing the fixing plate 13 of the oscillator unit 15 accommodated in the accommodation space 23 to the side of the first contact protrusion 47a.

As shown in FIGS. 6, 7, and 9, a plate gage 46 (spacer having a plate shape) is used as the bias means in the embodiment. The plate gage 46 is constituted by a block member having a rectangular solid shape and is manufactured by, for example, a metal such as stainless steel. The size of the plate gage 46 in the vertical direction is set slightly smaller than the size from the second seat shoulder 45 to the proximal surface of the case 16 (for example, about ¾), and the size the plate gage 46 in the lateral direction is set smaller than the distance between the second contact protrusions 47b (for example, about ⅓).

The thickness of the plate gage 46 is designed so as to be equal to or slightly larger than the length of the sum of the protrusion length L of the second contact protrusion 47b and the clearance C. That is, the thickness of the plate gage 46 is set so as to be able to maintain the state that the fixing plate 13 is made contact with the reference surfaces 48 by biasing the oscillator unit 15 at the side of the first contact protrusion 47a (direction shown by the arrow in FIGS. 7 and 9) when the plate gage 46 is inserted in the gap between the fixing plate 13 of the piezoelectric element 15 accommodated in the accommodation space 23 and the second inner wall surface 43b. Note that as for the bias force applied to the oscillator unit 15, a bias force caused by elastic deformation of the fixing plate 13 that is generated when the fixing plate 13 is pressed by the plate gage 46 is also included in addition to the bias force applied by the plate gage 46 itself.

When the oscillator unit 15 is attached in the accommodation unit 23 of the case 16 in the recording head 1 having the aforementioned structure, first, an adhesive agent is thinly applied on the distal surface of the free end 22 of the piezoelectric element 20. After an adhesive agent is applied, the fixing plate 13 is held by a jig, the distal end of the free end 22 is oriented to the accommodation space 23, and the oscillate unit 15 is inserted into the accommodation space 23 from the proximal side opening thereof. Then, the position of the oscillator unit 15 in the vertical direction is regulated by sitting the distal surface of the fixing plate 13 on the first seat shoulder 14.

Next, the fixing plate 13 is made contact with the reference surfaces 48 of the first contact protrusions 47a by inserting the plate gage 46 in the gap between the fixing plate 13 and the second inner wall surface 43b to regulate the position of the oscillator unit 15 in the thickness direction of the fixing plate (direction perpendicular to the direction in which the oscillators are arranged). Further, the arrangement position of the oscillator unit 15 in the oscillator arrangement direction is regulated by the third inner wall surface 43c and the fourth inner wall surface 43d. Herewith, the distal end of the free end 22 of the piezoelectric element 20 is precisely positioned in the state where the distal end is made contact with the surface of the corresponding island portion 24.

In the positioned state, an adhesive agent having flow property is injected from the proximal surface side of the case 16, and by utilizing capillary phenomenon, for example, the adhesive agent is filled between the wall surfaces and the fixating plate 13 from the first seat shoulder 44 to the second seat shoulder 45. Then, the adhesive agent at the distal end of the fee end 22 and the adhesive agent between the inner wall surfaces of the case 16 and the fixing plate 13 are cured. For example, the adhesive agent is cured by heating to a predetermined temperature and by leaving for an appropriate time in the heated state. Herewith, the fixing plate 13 and the case inner wall are bonded in the state where the oscillator unit 15 is positioned appropriately, and the distal end of the free end 22 is bonded to the island portion 24.

In this manner, in the recording head 1 according to the invention, the oscillator unit 15 is accommodated in the accommodation space 23 and the fixing plate 13 is made contact with the reference portion (first contact protrusion 47a) by a bias force applied by the bias means (plate gage 46) to regulate the arrangement position of the oscillator unit 15 in the accommodation space 23. Accordingly, the oscillator unit 15 can be accommodated in and fixed to the accommodation space 23 with a high positioning accuracy while assuring the clearance C which is necessary for assembling operation. Herewith, displacement of the distal end of the free end 22 of the piezoelectric element 20 with respect to the island portion 24 can be prevented, which makes it possible to improve productivity. As a result, deterioration of ejecting property of ink caused by displacement of the distal end of the free end with respect to the island portion 24 can be restrained.

Further, in the embodiment, the reference portion is constituted by at least not less than two first contact protrusions 47a protruded from the inner wall surface of the accommodation space 23, and the distal surfaces of the first contact protrusions 47a uniformed in a same surface is used as the reference surfaces 48 which become a reference for the arrangement position of the oscillator unit 15. Accordingly, the position of the oscillator unit 15 can be regulated in the state which is closer to a point contact state than the case where an entire surface among the inner walls of the accommodation space 23 is used as the reference surface. Herewith, the positioning accuracy can be further enhanced.

Further, in the embodiment, the plate gage 46 is used for the bias means, so that arrangement position of the oscillator unit 15 can be more surely regulated by pressing the fixing plate 13 with a surface of the plate gage 46.

The invention is not limited to the aforementioned first embodiment, and various modifications can be made based on the description of the scope of Claims.

In the first embodiment, the plate gage 46 is exemplified as the bias means. However, the bias means is not limited to the plate gage 46, and bias means having any structure can be used as long as the bias means can bias the oscillator unit 15 to the side of the first contact protrusion 47a.

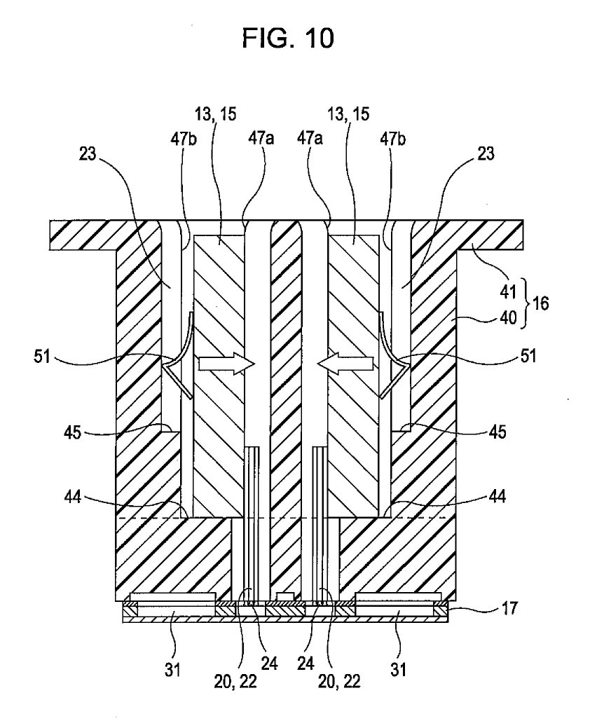

For example, as in a second embodiment shown in FIG. 10, the bias means may be a plate spring 51. The plate spring 51 is formed by bending a thin metal plate to have an approximately V-shape, and the plate spring 51 is attached to the back surface of the fixing plate 13 so that the bent side is disposed at the side of the second inner wall 43b. The plate spring 51 can provide a larger elastic deformation amount as compared with the plate gage 14, so that there is an advantage in that the size administration can be made roughly.

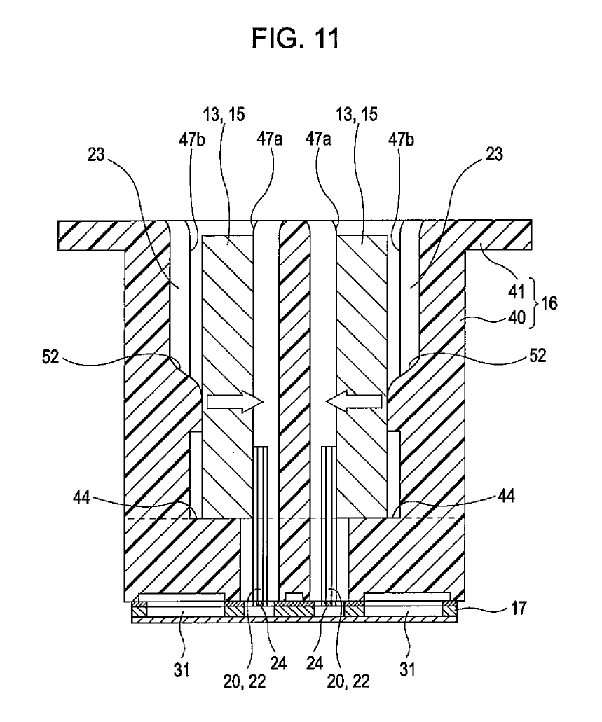

Further, as in a third embodiment shown in FIG. 11, the bias means may be constituted by a rib 52 provided to protrude toward the first inner wall surface 43a side from the second inner wall surface 43b in the accommodation space 23. The protrusion length of the rib 52 is designed approximately equal to or slightly larger than the length of the sum of the protrusion length L of the second contact protrusion 47b and the clearance C similarly to the thickness of the plate gate 46. Further, the upper portion of the rib 52 is an insertion guide having a tapered shape that is downwardly inclined. The tapered shape assures easiness of inserting the oscillator unit 15. With the structure, the rib 52 can be integrally formed with the case 16, so that it is not necessary to separately prepare bias means. Further, labor for accommodating bias means in the accommodation space 23 can be omitted.

Further, in the first embodiment, the structure is exemplified in which the first contact protrusion 47a is used as the reference portion (contact protrusion) of the invention and the distal surface thereof is used as the reference surface 48. However, the reference portion and the reference surface 48 are not limited to the first contact protrusion 47a and the distal surface thereof. A structure may be employed in which the second contact protrusion 47b is used as the reference portion (contact protrusion) and the distal surface 49 is used as the reference surface, and the back surface side of the fixing plate 13 is made contact with the second contact protrusion 47b by a bias force applied by bias means.

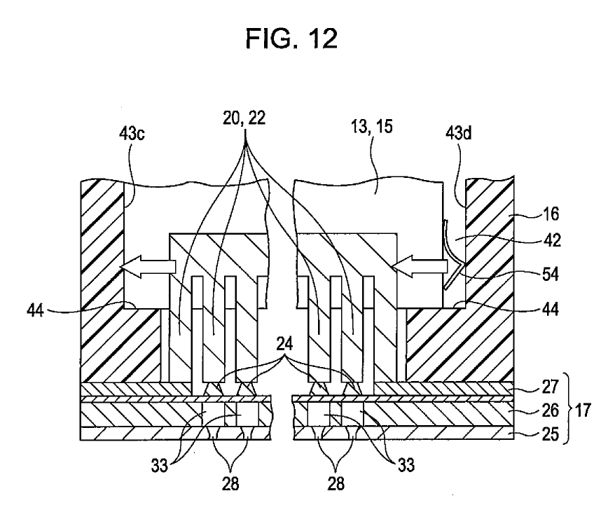

Further, in the above each embodiment, the positioning of the oscillator unit 15 in the accommodation space 23 in the thickness direction of the fixing plate is described. However, as in a fourth embodiment shown in FIG. 12, the invention cam be also applied to a positioning of the oscillator unit 15 in the accommodation space 23 in the piezoelectric element arrangement direction.

In the fourth embodiment, the size of the second accommodation space 43 in the piezoelectric element arrangement direction is set fully larger than the size of the fixing plate 13 in the width direction. The inner wall surface (third inner wall surface 43c) opposing one side surface (left side surface in FIG. 12) of the fixing plate 13 serves as the reference portion of the invention. Then, by providing bias means (for example, plate spring 54) in the gap between the fourth inner wall surface 43d opposing the third inner wall surface 43c and the other side surface of the fixing plate 13 (right side surface in FIG. 12), the one side surface of the fixing plate 13 is made contact with the third inner wall surface 43c by the bias force applied by the bias means to regulate the position of the oscillator unit 15 in the piezoelectric element arrangement direction. Herewith, displacement of the distal end of the free end 22 of the piezoelectric element 20 in the piezoelectric element arrangement direction with respect to the island portion 24 can be prevented.

The recording head 11 is exemplified as a liquid ejecting head in the above description. However, the invention can be also applied to another liquid ejecting head. For example, the invention can be also applied to a coloring material ejecting head used for manufacturing a color filter such as a liquid crystal display, an electrode material ejecting head used for forming electrodes such as an organic EL (Electro Luminescence) display, an FED (Field Emission Display), or the like, a bio-organic substance ejecting head used for manufacturing a bio-chip, and the like.

The entire disclosure of Japanese Patent Application No. 2007-257736, filed Oct. 1, 2007 is incorporated by reference herein.

What is claimed is:

1. A manufacturing method of a liquid ejecting head including an unit having a piezoelectric element and a fixing plate supporting the piezoelectric element, a case having an accommodation space for accommodating the unit, and a flow path unit having a vibration plate, a reference portion which becomes a reference of an arrangement position of the unit in the accommodation space being provided on at least a surface among inner wall surfaces partitioning the accommodation space, the manufacturing method of the liquid ejecting head comprising:
regulating the arrangement position of the unit in the accommodation space by accommodating the unit in the accommodation space and by making contact of the fixing plate with the reference portion by a bias force applied by a bias member; and
bonding and fixing the piezoelectric element and the vibration plate and bonding and fixing the fixing plate and the case in the state where the arrangement position of the unit is regulated.

2. A liquid ejecting head including an unit having a piezoelectric element and a fixing plate supporting the piezoelectric element, a case having an accommodation space for accommodating the unit, and a flow path unit having a vibration plate, the liquid ejecting head comprising:
a reference portion which becomes a reference of an arrangement position of the unit in the accommodation space, the reference portion being provided at least on a surface among inner wall surfaces partitioning the accommodation space; and
a bias member for biasing the fixing plate of the unit accommodated in the accommodation space to the reference portions side, wherein
the arrangement position of the unit in the accommodation space is regulated by accommodating the unit in the accommodation space and by making contact of the fixing plate with the reference portion by a bias force applied by the bias member, and
the piezoelectric element and the vibration plate are bonded and fixed and the fixing plate and the case are bonded and fixed in the state where the arrangement position of the unit is regulated.

3. The liquid ejecting head according to claim 2, wherein the reference potion is constituted by contact protrusions protruding from the inner wall surface of the accommodation space, a distal surface of each contact protrusion uniformed in a same surface is used as a reference surface which becomes a reference of the arrangement position of the unit, and the fixing plate of the unit is made contact with the reference surface by a bias force applied by the bias member.

4. The liquid ejecting head according to claim 2, wherein the bias member is constituted by a plate gage.

5. The liquid ejecting head according to claim 2, wherein the bias member is constituted by a plate spring.

6. The liquid ejecting head according to claim 2, wherein the bias member is constituted by a rib provided on one of the wall surfaces of the accommodation space, the wall surface opposing the wall surface on which the contact protrusions are provided.

7. A liquid ejecting apparatus comprising the liquid ejecting head according to claim 1.
